(19) United States
(12) Patent Application Publication
(10) Pub. No.: US 2024/0301573 A1
(43) Pub. Date: Sep. 12, 2024

(54) BISMUTH-BASED CO-CATALYST ARRANGEMENT

(71) Applicant: The Regents of the University of Michigan, Ann Arbor, MI (US)

(72) Inventors: Zetian Mi, Ann Arbor, MI (US); Wan Jae Dong, Ann Arbor, MI (US)

(21) Appl. No.: 18/599,611

(22) Filed: Mar. 8, 2024

Related U.S. Application Data
(60) Provisional application No. 63/450,894, filed on Mar. 8, 2023.

(51) Int. Cl. C25B 11/052; C23C 14/18; C23C 14/24; C25B 9/19; C25B 9/50; C25B 11/02; C25B 11/059; C25B 11/091; C30B 23/02; C30B 29/40; C30B 29/60; C25B 3/07; C25B 3/26

(52) U.S. Cl. CPC C25B 11/052; C23C 14/18; C23C 14/24; C25B 9/19; C25B 9/50; C25B 11/02; C25B 11/059; C25B 11/091; C30B 23/025; C30B 29/406; C30B 29/605; C25B 3/07; C25B 3/26

(57) ABSTRACT

A device for catalytic conversion of carbon dioxide (CO₂) includes a substrate having a surface, an array of conductive projections supported by the substrate and extending outward from the surface of the substrate, each conductive projection of the array of conductive projections having a semiconductor composition, and a plurality of nanoparticles disposed over the array of conductive projections, each nanoparticle of the plurality of nanoparticles being configured for the catalytic conversion of carbon dioxide (CO₂). Each nanoparticle of the plurality of nanoparticles includes a Group VA element, the Group VA element being a metal or a metalloid.

### CROSS-REFERENCE TO RELATED APPLICATION

This application claims the benefit of U.S. provisional application entitled “Bismuth-Based Co-Catalyst Arrangement,” filed Mar. 8, 2023, and assigned Ser. No. 63/450,894, the entire disclosure of which is hereby expressly incorporated by reference.

### STATEMENT REGARDING FEDERALLY SPONSORED RESEARCH OR DEVELOPMENT

This invention was made with government support under Contract No. W911NF-21-1-0337 awarded by the U.S. Army Research Office. The government has certain rights in the invention.

### BACKGROUND OF THE DISCLOSURE

### Field of the Disclosure

The disclosure relates generally to photoelectrochemical and other chemical conversion of carbon dioxide (CO₂).

### Brief Description of Related Technology

The ever-increasing CO₂ emissions associated with fossil-based energy consumption have led to serious environmental concerns. The CO₂ reduction reaction has been considered as a promising solution to overcome this challenge. To improve the activity of the CO₂ reduction reaction, a number of electrocatalysts have been developed and achieved relatively high selectivity and productivity at low overpotential for single-carbon (CO, CH₄, and HCOOH) and multi-carbon products (C₂H₄, C₂H₆, and C₂H₅OH). If the electrocatalysts are integrated with renewable energy sources, net CO₂ reduction could be realized while simultaneously producing value-added feedstock. Therefore, solar-driven photoelectrochemical (PEC) CO₂ reduction based on semiconductor photoelectrodes is believed to be one of the most attractive approaches because of solar energy's infinite reservoir and environmental benignancy.

Various kinds of semiconductors such as Si, III-V, and metal oxides have demonstrated PEC CO₂ reduction. However, these semiconductors usually suffer from insufficient light absorption, sluggish charge carrier transport, photocorrosion, or most importantly poor catalytic activity. Therefore, a surface cocatalyst has been used to improve the catalytic activity of the PEC CO₂ reduction.

Noble metals such as Au, Ag, and their alloys have been decorated on photocathodes as cocatalysts. However, these noble metals are too expensive for practical application. Inexpensive and earth-abundant cocatalysts have accordingly been studied and developed for electrocatalytic CO₂ reduction. Sn and Bi metals have shown promise for converting CO₂ to formic acid (HCOOH). However, the effective utilization of earth-abundant cocatalysts in PEC CO₂ reduction still remains a grand challenge due to inefficient light trapping, limited surface area, poor stability, and insufficient activity of semiconductor photocathodes.

Single-crystal GaN nanowires (GaN nanowires) vertically grown on Si photocathodes have emerged as an efficient and stable platform to achieve high performance CO₂ reduction as well as water splitting. To date, however, there have been few studies of interfacial interactions between the semiconductor and cocatalyst materials to achieve satisfactory catalytic performance. For instance, interfacial interaction between two different materials changes the electronic structure, alters the binding energies of reaction intermediates, and consequently tunes the catalytic pathway. Therefore, the composition and structure of multi-composite catalysts can yield unique catalytic properties that cannot be obtained with a single catalyst material. Nonetheless, little attention has been paid to the interfacial electronic effects induced by the interaction between semiconductor and cocatalyst materials on PEC catalysis, owing to the complexity of the heterogeneous interface, the difficulty of fabricating high-quality semiconductor material, and the poor stability of conventional photocathodes in aqueous media.

### SUMMARY OF THE DISCLOSURE

In accordance with one aspect of the disclosure, a device for catalytic conversion of carbon dioxide (CO₂) includes a substrate having a surface, an array of conductive projections supported by the substrate and extending outward from the surface of the substrate, each conductive projection of the array of conductive projections having a semiconductor composition, and a plurality of nanoparticles disposed over the array of conductive projections, each nanoparticle of the plurality of nanoparticles being configured for the catalytic conversion of carbon dioxide (CO₂). Each nanoparticle of the plurality of nanoparticles includes a Group VA element, the Group VA element being a metal or a metalloid.

In accordance with another aspect of the disclosure, a photocathode for a photoelectrochemical cell includes a substrate including a semiconductor material, the semiconductor material being doped to generate charge carriers upon solar illumination, an array of nanostructures supported by the substrate, each nanostructure of the array of nanostructures being configured to extract the charge carriers from the substrate, each nanostructure of the array of nanostructures including gallium nitride, and a plurality of nanoparticles distributed across each nanostructure of the array of nanostructures, each nanoparticle of the plurality of nanoparticles being configured for the catalytic conversion of carbon dioxide (CO₂) in the photoelectrochemical cell into formic acid. Each nanoparticle of the plurality of nanoparticles includes a Group VA element, the Group VA element being a metal or a metalloid.

In accordance with yet another aspect of the disclosure, a method of fabricating a device for catalytic conversion of carbon dioxide (CO₂) includes growing an array of conductive projections on a semiconductor substrate, each conductive projection of the array of conductive projections having a semiconductor composition, and depositing a plurality of nanoparticles across each conductive projection of the array of conductive projections, each nanoparticle of the plurality of nanoparticles being configured for the catalytic conversion of carbon dioxide (CO₂). Each nanoparticle of the plurality of nanoparticles includes a Group VA element, the Group VA element being a metal or a metalloid.

In connection with any one of the aforementioned aspects, the devices and/or methods described herein may alternatively or additionally include or involve any combination of one or more of the following aspects or features. The Group VA element is bismuth. The Group VA element is selected from the group consisting of antimony and bismuth. Respective nanoparticles of the plurality of nanoparticles have a core-shell arrangement in which a core includes the Group VA element and a shell includes an amorphous oxide material. The shell has a thickness falling in a range from about 2 nm to about 5 nm. The substrate includes a semiconductor material. The semiconductor material is doped to define a junction to generate charge carriers upon absorption of solar radiation. Each conductive projection of the array of conductive projections includes a nanowire configured to extract the charge carriers generated in the substrate. The substrate includes silicon. The semiconductor composition includes gallium nitride. Respective nanoparticles of the plurality of nanoparticles have a size falling in a range from about 3 nm to about 20 nm. An electrochemical system includes a working electrode configured as described or claimed herein, and further includes a counter electrode, an electrolyte in which the working and counter electrodes are immersed, and a voltage source that applies a bias voltage between the working and counter electrodes. The bias voltage is set to a level for conversion of CO₂ into formic acid at the working electrode. A photoelectrochemical system includes a working photocathode configured as described or claimed herein, and further includes a counter electrode, an electrolyte in which the working photocathode and the counter electrode are immersed, and a voltage source that applies a bias voltage between the working photocathode and the counter electrode. The bias voltage is set to a level for conversion of CO₂ into formic acid at the working photocathode. Forming the array of conductive projections includes growing an array of nanowires on the semiconductor substrate, each nanowire of the array of nanowires having a semiconductor composition for the catalytic conversion of carbon dioxide (CO₂). Growing the array of nanowires includes implementing a molecular beam epitaxy (MBE) procedure under nitrogen-rich conditions. Depositing the plurality of nanoparticles includes implementing a thermal evaporation procedure to deposit bismuth nanoparticles on the array of conductive projections.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) a schematic illustration of the fabrication of a photocathode by MBE growth of single-crystal GaN nanowires on a Si p-n wafer and thermal evaporation of bismuth (Bi) nanoparticles in accordance with one example, as well as 45°-tilted-view and top-view (inset) SEM images of (b) a GaN/Si array and (c) a Bi/GaN/Si photocathode in accordance with one example.

FIG. 2 depicts (a) TEM and (b) HAADF-STEM images of a Bi/GaN/Si photocathode in accordance with one example in which polycrystalline Bi nanoparticles were uniformly distributed on single-crystal GaN nanowires and about 2 nm of amorphous oxide was formed on the surface of Bi nanoparticles, as well as (c) a high-resolution TEM image and electron diffraction patterns at the Bi/GaN interface.

FIG. 3 depicts graphical plots of x-ray photoelectron spectroscopy (XPS) spectra of (a) Ga 2p_{3/2}, (b) N 1s, and (c) Bi 4f for (i) an example GaN/Si photocathode, (ii) an example Bi/GaN/Si photocathode, and (iii) an example Bi/GaN/Si photocathode after implementation of a CO₂ reduction reaction, depicting that the peak positions of Ga 2p_{3/2} and N 1s spectra positively shifted after coating of Bi nanoparticles, indicating strong electronic interaction between GaN nanowires and Bi nanoparticles.

FIG. 4 depicts (a) a schematic view of photoelectrochemical CO₂ reduction and an energy diagram in connection with a Bi/GaN/Si photocathode in accordance with one example, as well as graphical plots of (c) LSV curves, (d) FE_{HCOOH}, and (e) j_{HCOOH} of (i) an example Si wafer, (ii) an example Bi/Si photocathode, (iii) an example GaN/Si photocathode, and (iv) an example Bi/GaN/Si photocathode in CO₂-purged 0.1 M KHCO₃ electrolyte, in which the thickness of the Bi layer or film was 10 nm for the Bi/Si and Bi/GaN/Si examples, as well as (f) a graphical plot of Bi thickness dependent FE_{HCOOH} (left axis) and j_{HCOOH} (right axis) of example Bi/GaN/Si photocathodes at potentials of −0.2, −0.4 and −0.6 V_{RHE}.

FIG. 5 depicts (a) a graphical plot of free-energy profiles for the CO₂ reduction reaction to HCOOH and CO on Bi₂O₃ and Bi₂O₃/GaN(101̅0), with the inset depicting differential charge density for a Bi₂O₃/GaN(101̅0) system, in which blue indicates electron reduction and yellow indicates electron accumulation, as well as (b) a graphical plot of density of states of Bi₂O₃/GaN(101̅0).

FIG. 6 is a schematic view and block diagram of an electrochemical system having a working electrode with a nanowire-nanoparticle architecture for catalytic conversion of carbon dioxide (CO₂) in accordance with one example.

FIG. 7 is a flow diagram of a method of fabricating a device (e.g., a photocathode) for catalytic conversion of carbon dioxide (CO₂) for catalytic conversion of CO₂ in accordance with one example.

The embodiments of the disclosed devices, systems, and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Electrodes of photoelectrochemical and other chemical cells having a conductive projection (e.g., nanowire) array with nanoparticles for conversion (e.g., reduction) of carbon dioxide (CO₂) into, e.g., formic acid, are described. Methods of fabricating photocathodes and other electrodes for use in photoelectrochemical and other chemical systems are also described. The conductive projection (e.g., nanowire) array has a semiconductor composition. The nanoparticles are configured for catalytic conversion of carbon dioxide (CO₂). As described herein, the nanoparticles include a Group VA metalloid or metal, such as bismuth (Bi) or antimony (Sb). The compositions of the conductive projections (e.g., nanowires) and nanoparticles together provide a useful co-catalyst interface for CO₂ reduction.

The co-catalyst arrangement involving Group VA (e.g., bismuth) nanoparticles and GaN nanowires yields a number of benefits. The interfacial interaction between the materials of the nanoparticles and nanowires allows the photoelectrode to be tuned for improvements in catalytic activity for CO₂ reduction. As described herein, the exceptional catalytic synergy at the interface of the two materials allows the co-catalyst arrangement to achieve improved selectivity, productivity, and stability in the CO₂ reduction reaction.

Described herein are example photocathodes and other devices and systems that utilize the electronic interaction between Bi nanoparticles and GaN nanowires grown on planar Si wafers to achieve improved PEC CO₂ reduction reaction performance. The unique atomic ordering and electronic properties of defect-free GaN nanowires showed enormous utility for efficient CO₂ conversion when integrated with Bi nanoparticle cocatalysts. As described below, X-ray photoelectron spectroscopy (XPS) measurement and density functional theory (DFT) calculations indicate strong electronic interaction via sharing of electrons between the Bi nanoparticles and GaN nanowires. This interaction lowered the thermodynamic reaction barriers and further facilitated electron transport. The reaction mechanism of the Bi/GaN system is different from previous CO₂ reduction over Bi electrocatalysts or GaN photocathodes. As a result, the integration of Bi nanoparticles on GaN nanowires greatly improved faradaic efficiency of HCOOH (FE_{HCOOH}) to about 98% at −0.3 V_{RHE}, achieved a high current density of HCOOH (j_{HCOOH}) of 10.3 mA/cm² at −0.6 V_{RHE}, and operated 12 hours without degradation under 1-sun light illumination.

These improvements are achieved despite the challenges presented via the integration of the co-catalysts. For instance, the loading of the Bi nanoparticles on the nanowires can be challenging due to aggregation, which leads to an undesirably large nanoparticle. But the size of the nanoparticles can affect both catalytic performance and light absorption. For instance, as described below, nanoparticles that are too large may adversely affect light absorption by the photocathode.

The Bi nanoparticles are supported by an architecture including a conductive projection (e.g., nanowire) array. One-dimensional (1-D) nanostructured metal nitrides, such as Gallium nitride (GaN) nanowires (GaN nanowires), are useful in solar fuels production and capable of being grown via molecular beam epitaxy (MBE) defect-free on planar silicon. The heterostructure of the GaN nanowires presents a large surface-to-volume ratio, which is beneficial for sunlight harvesting and catalyst loading with a dramatically reduced amount, but high-density, of catalytic centers. Furthermore, the defect-free structure and high charge carrier mobility of GaN nanowires lead to charge carrier extraction from the silicon substrate. The electronic properties of gallium nitride are useful for activating the stable carbon dioxide molecule, thereby presenting a useful platform for supporting nanoparticles to construct an effective nanoarchitecture for solar-driven CO₂ conversion.

As described herein, the nanowires (e.g., GaN nanowires) are disposed on a planar semiconductor substrate (e.g., silicon) to provide a useful scaffold for loading the Bi nanoparticles to construct a productive architecture (e.g., nanoarchitecture) for CO₂ conversion. The disclosed architectures may accordingly, in some cases, be free of noble metals. Nonetheless, high-efficiency sunlight collection is achieved via high-density active sites with a superior nanoparticle (e.g., a Bi nanoparticle), as well as effective charge carrier extraction.

Although described herein in connection with electrodes having GaN-based nanowire arrays for PEC CO₂ reduction, the disclosed electrodes are not limited to PEC reduction or GaN-based or other nanowires. A wide variety of types of chemical cells may benefit from use of the conductive projection (e.g., nanowire)-nanoparticle interface, including, for instance, electrochemical cells and thermochemical cells. Moreover, the nature, construction, configuration, characteristics, shape, and other aspects of the conductive projections, as well as the structures on or to which the conductive projections (e.g., nanowires) and/or nanoparticles are deposited, may vary. The disclosed electrodes, systems, and methods may also be directed to CO₂ reduction products other than or in addition to formic acid, such as CO, CH₃OH, CH₄, C₂H₄, C₂H₅OH, and C₂H₆.

Although described herein in connection with Bi nanoparticles, the disclosed devices, systems, and methods may use alternative or additional metals. For example, the nanoparticles may be composed of, or otherwise include, antimony (Sb), or another metal or metalloid Group VA element, or combinations thereof.

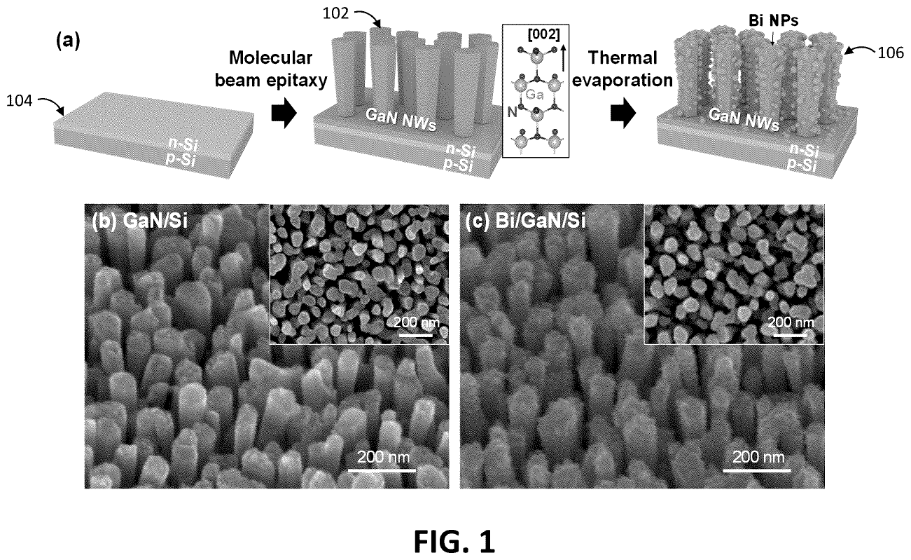

FIG. 1 depicts the fabrication of a device 100 for catalytic conversion of carbon dioxide in accordance with one example. In this case, the device is or includes a Bi/GaN/Si photocathode fabricated via plasma-assisted molecular beam epitaxy (MBE) growth of GaN nanowires 102 on a n+-p silicon substrate 104, followed by thermal evaporation of Bi nanoparticles 106, as shown in part (a) of FIG. 1.

Scanning electron microscopy (SEM) images of examples of the Bi/GaN/Si photocathode showed the vertically grown GaN nanowires on the planar n⁺-p Si wafer. In these examples, the average length of GaN nanowires was about 288 nm and the average diameter was about 60 nm (FIG. 1, part b). After the decoration of 10 nm-thick Bi nanoparticles, the surface morphology of GaN nanowires was roughened (FIG. 1, part c). The presence of Bi nanoparticles was further confirmed by energy-dispersive X-ray spectroscopy (EDS) analysis. X-ray diffraction (XRD) patterns of a GaN/Si device and an example Bi/GaN/Si photocathode showed GaN (002), GaN (004), and Si (004) peaks. However, because the grain sizes of the Bi nanoparticles were too small, the XRD peaks from the Bi nanoparticles were not detected.

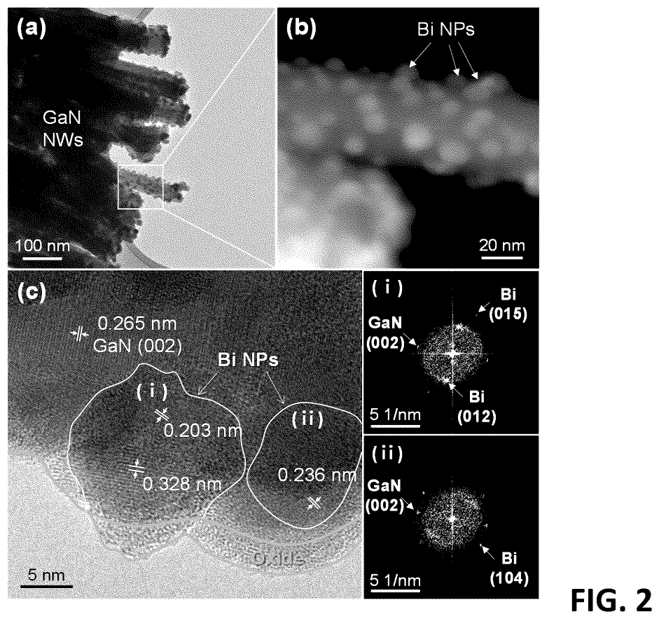

In order to confirm the microstructure and atomic distribution of the GaN nanowires and Bi nanoparticles, scanning transmission electron microscopy (STEM) studies were performed. The Bi nanoparticles were uniformly distributed on or across the array of GaN nanowires (FIG. 2, part a). Because the atomic number difference between Ga (31) and Bi (83) is fairly large, sufficient Z-contrasts were obtained from the locally segregated Bi nanoparticles on the GaN nanowires in high angular annular dark field (HAADF)-STEM images (FIG. 2, part b). In the STEM images, the size of the Bi nanoparticles was statistically calculated by computer software. In these examples, the average size was measured to be 9.1 nm. High-resolution transmission electron microscope (HR-TEM) images and selected area electron diffraction patterns also evidenced the Bi nanoparticles on the GaN nanowires (FIG. 2, part c). Lattice fringes were observed with d-spacings of 0.203, 0.236, 0.265, and 0.328 nm, which correspond to Bi (015), Bi (104), GaN (002), and Bi (012) planes, respectively. These studies establish that polycrystalline Bi nanoparticles were formed on single-crystal GaN nanowires. Moreover, the surface of the Bi nanoparticles was covered with amorphous oxide having a thickness of about 2 nm, indicating a metal/oxide core/shell structure.

The morphology of the Bi nanoparticles was investigated after implementation of the CO₂ reduction reaction for 20 min at −0.4 V_{RHE} in 0.1 M KHCO₃. The presence of Bi nanoparticles having a size of about 3 to about 20 nm was evident on the GaN nanowires, indicating that the Bi nanoparticles were stably anchored on the surface of GaN nanowires without a noticeable change in morphology.

Crystallographic orientations of the Bi nanoparticles were investigated by lattice fringes and electron diffraction patterns. Bi (012) plane with a lattice spacing of 0.328 nm, Bi₂O₂CO₃ (013) plane with a lattice spacing of 0.295 nm, and Bi₂O₃ (002) plane with a lattice spacing of 0.346 nm were observed. The outermost surface of cocatalysts was passivated by the amorphous region with thickness of about 2 nm to about 5 nm. The oxidized forms of Bi₂O₂CO₃, Bi₂O₃, and amorphous oxides may have been transformed from metallic Bi by immersing the sample in the aqueous electrolyte. There may be unavoidable partial reduction of the oxidized Bi species to metallic Bi during the CO₂ reduction reaction. However, the bismuth-oxygen structure can remain during the CO₂ reduction reaction at cathodic potentials as confirmed by operando Raman and in-situ X-ray absorption near-edge structure measurements. Hence, it is concluded that the Bi nanoparticles acting in the catalytic reaction were composed of not only metallic Bi and but also oxidized forms.

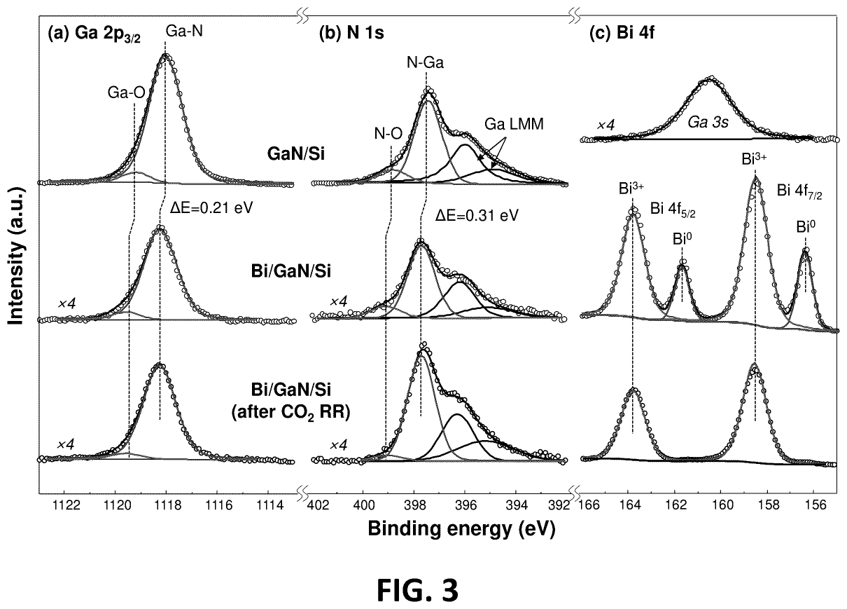

X-ray photoelectron spectroscopy (XPS) was carried out to study the surface bonding states of example photoelectrodes. Ga 2p_{3/2} XPS spectra were separated with a major peak of Ga—N bond (1118.0 eV) and a minor peak of Ga—O bond (1119.2 eV) (FIG. 3, part a). After depositing Bi nanoparticles, the peak intensity of Ga 2p_{3/2} XPS spectra reduced by about four times because Bi nanoparticles screened the photoelectrons emitted from GaN nanowires. Moreover, the Ga 2p_{3/2} spectrum of Bi/GaN/Si positively shifted about 0.21 eV compared to GaN/Si likely due to electron donation from GaN nanowires to Bi nanoparticles. After the CO₂ RR for 20 min in 0.1 M KHCO₃ at −0.4 V_{RHE}, XPS spectra were approximately the same. This indicates that the chemical bonding states of GaN nanowires did not change during the PEC CO₂ reduction reaction. In N 1s XPS spectra, N—Ga (398.4 eV) and N—O (399.8 V) bonds were detected with Ga LMM Auger electrons (FIG. 3, part b). Similar to Ga 2p_{3/2} XPS results, the intensity of N 1s decreased after deposition of the Bi nanoparticles and shifted positively by about 0.31 eV, revealing electron transfer and strong electronic interaction between the GaN nanowires and Bi nanoparticles. A positive shift of Ga 2p_{3/2} and N 1s spectra implied that the GaN nanowires donate electrons to the Bi nanoparticles. The spontaneous electron transfer from the GaN nanowires to the Bi nanoparticles is further addressed below.

To elucidate the bonding states of the Bi nanoparticles, deconvolution of Bi 4f XPS spectra was carried out with metallic Bi⁰ (156.4 and 161.7 eV) and Bi³⁺ (158.5 and 163.8 eV) bonds (FIG. 3, part c). The GaN nanowires showed a peak from Ga 3s electrons without the characteristic doublet peaks of Bi 4f_{7/2} and Bi 4f_{5/2} spectra. In contrast, the example Bi/GaN/Si photocathode exhibited a metallic Bi⁰ peak and an intense Bi³⁺ peak. The Bi³⁺ peak remained on the surface even after the CO₂ reduction reaction due to spontaneously formed Bi₂O₂CO₃, Bi₂O₃, and amorphous oxides on the surface of the Bi nanoparticles in the aqueous electrolyte as described in the TEM results. Despite the possible partial reduction of Bi₂O₂CO₃ and Bi₂O₃ during the CO₂ reduction reaction, the Bi³⁺ states may dominate the outer surface layer where catalytic reaction occurs.

To investigate the oxidation states of surface oxides, O 1s XPS spectra were fitted with four peaks of O—Ga (531.1 eV), O—Bi (529.4 eV), OH—Bi (530.9 eV), and absorbed H₂O (532.2 eV). It was found that the oxide (O—Bi) and hydroxide (OH—Bi) were the reason for the Bi³⁺ peaks. Even after the PEC CO₂ reduction reaction, the presence of O—Bi and OH—Bi bonds showed that Bi oxides remain at the outermost layer of the Bi nanoparticles.

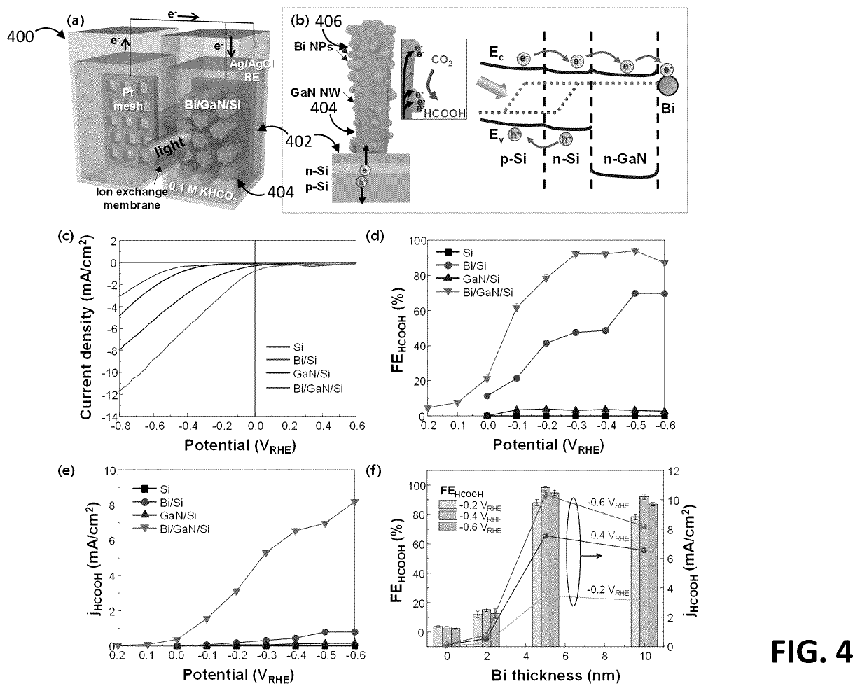

The performance of the above-described examples in a photoelectrochemical CO₂ reduction reaction 400 is now described in connection with FIG. 4. A n⁺-p Si substrate 402 with a narrow bandgap (about 1.1 eV) was photoexcited by solar irradiation to generate electron-hole pairs for the reaction (see parts (a) and (b) of FIG. 4). The light absorption of GaN nanowires 404 is relatively negligible due to their large bandgap (about 3.4 eV). However, the GaN nanowires 404 improve the light absorption of the planar Si substrate 402 by reducing the Fresnel reflection because the geometry of the nanowires 404 is useful for matching the refractive indices between the air and the Si substrate 402. Moreover, the GaN nanowires 404 function as a useful geometric modifier to load cocatalysts 406 (e.g., Bi nanoparticles) for enhancing the catalytic reaction 400. In this architecture, the light-harvesting and catalytic behavior is spatially decoupled, enabling the optical and catalytic properties to be rationally manipulated to achieve optimum performance. As shown in the energy diagram of the electrode (part (b) of FIG. 4), the electron transport is also feasible without an energy barrier between the GaN nanowires 404 and the Si substrate 402.

The PEC CO₂ reduction reaction was performed by illuminating light (AM 1.5 G 100 mW/cm²) directed to the example Bi/GaN/Si photocathode in the surface normal direction and applying electrical potential using a three-electrode configuration (FIG. 4, part a). The n⁺-p Si wafer with a small bandgap (about 1.1 eV) readily generates electron-hole pairs by solar irradiation. The GaN nanowires enhance the light trapping in the Si substrate by suppressing the reflection loss. The average optical reflectance (OR) of Si substrate was 51.4% at wavelengths of falling in a range from about 400 to about 800 nm. In contrast, the GaN nanowires effectively reduced OR to 17.4% because the vertically-aligned arrangement of the nanowires matches the refractive indices between air and Si substrate. In addition, the Bi nanoparticles with a thickness (t_{Bi}) of about 10 nm on GaN nanowires functioned as light scattering centers, leading to enhanced light absorption, further reducing OR to 11.7%. In contrast, a Bi film (t_{Bi}=10 nm) formed on a planar Si wafer reflects the incident light and increased OR to 57.9%. The vertically aligned nanowires were found to be an excellent geometric framework to load the cocatalysts of Bi nanoparticles and enhance the optical transmittance by preventing Fresnel reflection. As shown in the energy band diagram of the photocathode, the transport of photoexcited electrons from Si to GaN is feasible without any significant barrier because conduction bands of n⁺-Si and n⁺-GaN are approximately aligned (FIG. 4, part b). Therefore, the photogenerated electrons readily migrate toward active sites of the Bi nanoparticles to participate in the CO₂ reduction reaction.

Linear sweep voltammetry (LSV) measurements were conducted to study the PEC CO₂ reduction performance of examples of planar Si, Bi/Si, GaN/Si, and Bi/GaN/Si in CO₂-purged 0.1 M KHCO₃ (FIG. 4, part c). The photocurrent densities (j) of Si and Bi/Si with t_{Bi}=10 nm were smaller than those of GaN nanowires due to the reflection loss and smaller surface area. Interestingly, GaN nanowires grown on Si substrate showed a significant improvement in an onset potential (0 V_{RHE}) and j (about 8.0 mA/cm² at −0.8 V_{RHE}) because of efficient light trapping, effective charge carrier transport, and suppressed recombination. Furthermore, after deposition of Bi nanoparticles on GaN nanowires (t_{Bi}=10 nm), j was further improved to 11.9 mA/cm² at −0.8 V_{RHE}. The photocathodes exhibited negligible activity in the dark condition, revealing that solar energy is used for the PEC reactions.

The influence of the applied potential on the Faradaic efficiencies was investigated for the Si, Bi/Si, GaN/Si, and Bi/GaN/Si examples. The FE_{HCOOH} results are summarized in Figure, part (d). Planar Si primarily produced H₂ with a little amount of CO (FE_{CO} less than 10%). Deposition of a Bi film on the Si substrate (Bi/Si) generated HCOOH at 0 V_{RHE} and showed a maximum FE_{HCOOH} of about 70% at −0.5 V_{RHE}. The GaN/Si photocathode predominantly produced H₂. However, the example Bi/GaN/Si photocathode greatly improved the selectivity of HCOOH and positively shifted the onset potential. High FE_{HCOOH} greater than 92% was achieved at −0.3 V_{RHE}, and the onset-potential was about 0.2 V_{RHE}. The thermodynamic energy barrier for the hydrogen evolution reaction (HER) on a Bi catalyst is much higher than that of the CO₂ reduction to HCOOH because the free energy of H adsorption is too positive to allow active HER. Therefore, H adsorption on the Bi/GaN/Si photocathode was inhibited and HER is largely suppressed. Because the example Bi/GaN/Si photocathode showed the best j and FE_{HCOOH} among the measured example photoelectrodes, j_{HCOOH} was also the highest. The maximum j_{HCOOH} of the example Bi/GaN/Si photocathode was 8.2 mA/cm² at −0.6 V_{RHE}, which was about 10 times higher than that of the Bi/Si example (0.8 mA/cm²) (FIG. 4, part e). What is more, the example Bi/GaN/Si photocathode exhibited the maximum applied bias photon-to-current efficiency (ABPE) of 0.15% at −0.1 V_{RHE}, whereas the other photocathodes of Si, Bi/Si, and GaN/Si exhibited low ABPE less than 0.01%. In comparison to the electrocatalytic performance of the Bi film, the example Bi/GaN/Si photocathode exhibited enormously improved onset potential, current density, and FE_{HCOOH} under solar light. Thus, the synergetic electronic interaction between the GaN nanowires and the Bi nanoparticles enhanced the conversion rate of CO₂ to HCOOH as well as the selectivity.

The products in the anodic compartment were also measured to investigate the oxidation reactions at the counter electrode. When cathodic potentials of −0.4 and −0.6 V_{RHE} were applied to the photocathode for 20 min, the faradaic efficiency of O₂ was nearly 100%, confirming that the oxygen evolution reaction was the only reaction occurring at the Pt counter electrode in the anodic reactor.

The catalytic activity of the example Bi/GaN/Si photocathodes was further investigated by tuning the size of the Bi nanoparticles, t_{Bi}. At a size t_{Bi} of about 2 nm, increments of FE_{HCOOH} and j_{HCOOH} were not noticeable compared to GaN/Si (t_{Bi}=0 nm) (FIG. 4, part f). However, deposition of 5 nm-thick Bi nanoparticles dramatically increased FE_{HCOOH} to 88.0%, 98.3%, and 94.7% at −0.2, −0.4, and −0.6 V_{RHE}, respectively. Accordingly, the maximum j_{HCOOH}=10.3 mA/cm² was achieved at −0.6 V_{RHE}. At a higher loading of Bi nanoparticles (t_{Bi}=10 nm), FE_{HOOCH} and j_{HCOOH} were slightly decreased to 87.0% and 8.2 mA/cm² at −0.6 V_{RHE}. The Bi nanoparticles provide active sites for catalyzing the reaction. Thus, both FE_{HCOOH} and j_{HCOOH} first improved with t_{Bi}. However, overloading of Bi nanoparticles can block the incident light and decrease the number of photogenerated electrons. Therefore, balancing the catalytic activity and optical transmittance of the Bi nanoparticles may lead to an optimized thickness t_{Bi} of about 5 nm.

The example Bi/GaN/Si photocathode exhibited high FE_{HCOOH} greater than 90% for 12 hours of operation. It is therefore seen that the Bi/GaN/Si photocathode is a useful photocathode for PEC CO₂ reduction with prolonged stability.

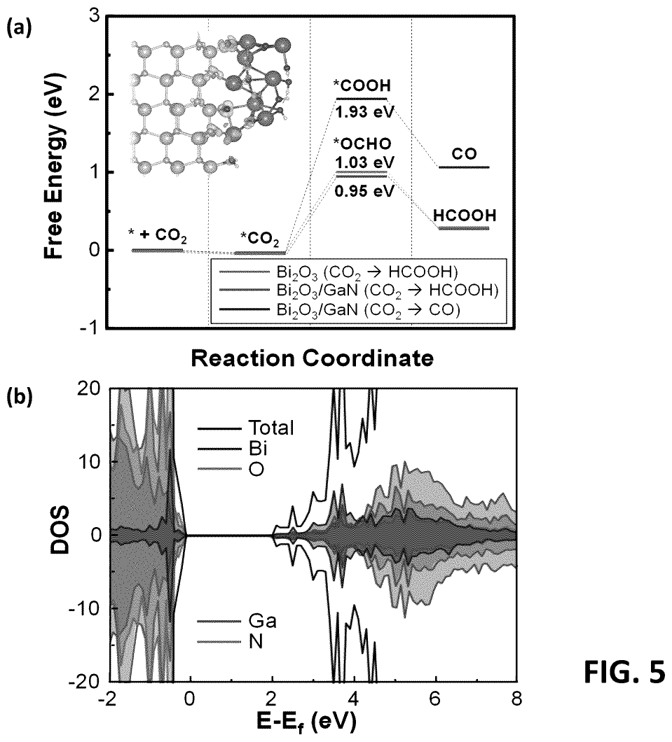

Density functional theory (DFT) calculations were carried out to gain more insight into the impact of interfacial interaction between the GaN nanowires and the Bi nanoparticles on the CO₂ reduction activity. Based on the TEM and XPS results that the outermost surface of Bi nanoparticles featured the oxidized Bi species in the form of Bi₂O₃, Bi₂O₂CO₃, or amorphous oxide/hydroxide, a Bi₂O₃/GaN(101̅0) model was established to elucidate the interfacial interaction. The geometries of GaN(101̅0) and Bi₂O₃ were optimized by considering the PEC CO₂ reduction reaction in an aqueous condition. Then, the free energy diagram of reducing CO₂ to HCOOH and CO with corresponding fully relaxed configuration was calculated. On the GaN(101̅0) surface, the limiting potential (μ) for CO₂ reduction to HCOOH via *OCHO intermediate was 2.10 eV and the u for CO production via *COOH intermediate was 1.93 eV. Due to the large thermodynamic potential barriers, the CO₂ reduction reaction on the GaN surface is unfavorable. On the other hand, self-supported Bi₂O₃ significantly stabilized *OCHO relative to *COOH, leading to dramatically reduced u of 1.04 eV for HCOOH production. Most strikingly, the μ value for HCOOH production was further lowered to 0.95 eV at the surface of Bi₂O₃/GaN(101̅0) whereas high u (1.93 eV) was retained for CO production (FIG. 5, part a), indicating that Bi₂O₃/GaN binary system predominantly converts CO₂ to HCOOH rather than CO. These results indicate that Bi₂O₃ cocatalyst supported on the GaN nanowires can greatly enhance the activity and selectivity of HCOOH. CO₂ reduction reaction by the Bi/GaN/Si photocathode followed the same reaction pathway to that of previous Bi-based catalysts through *OCHO intermediate. However, it should be noted that Bi₂O₃/GaN binary systems can further lower the thermodynamic energy barrier for HCOOH production by stabilizing *OCHO intermediate compared to self-supported Bi₂O₃ or GaN. To visualize the strong electronic interaction between the Bi nanoparticles and GaN nanowires, the differential charge density at Bi₂O₃/GaN(101̅0) interface was shown (Inset of FIG. 5, part a). After the junction, each interfacial Ga and Bi atoms lose Bader charge of 0.878e and 0.549e, respectively. Net charge transfer of 0.329e was observed at the Bi₂O₃/GaN interface. Electron reduction (blue) was found near the Ga atoms while electron accumulation (yellow) was found near the neighboring O atoms, revealing ionic Ga—O bond. Meanwhile, electrons accumulated at the middle region in between Bi and N atoms, suggesting the formation of a covalent Bi—N bond. The Ga—O and Bi—N bonds resulted in the stable anchoring of Bi nanoparticles on GaN nanowires.

Density of states (DOS) near the Fermi-level (E_{f}) of GaN was analyzed for GaN and Bi₂O₃/GaN systems to investigate the electron transfer properties between GaN nanowires and Bi nanoparticles. It is notable that the DOS at the conduction band edge (2.3<E−E_{f}<4 eV) was enlarged after the incorporation of Bi₂O₃ on the GaN. The enlarged DOS at this energy level was attributed to the atomic Bi and O (FIG. 5, part b), indicating that the energy states of Bi₂O₃ positions slightly lower than the conduction band edge of GaN. This conduction band alignment facilitates the spontaneous transfer of photoelectrons without notable charge carrier transfer resistance. The thermodynamically favorable HCOOH production on the Bi nanoparticles and efficient charge carrier transfer from GaN nanowires to Bi nanoparticles induces photogenerated electrons to move toward the Bi nanoparticles during the PEC CO₂ reduction reaction. Although the Bi₂O₃/GaN model cannot fully explain all possible combinations of Bi—GaN binary systems, it is still a very useful finding that the synergetic effect of the semiconductor and the cocatalyst enhances the catalytic activity compared to each single material.

Previously, Bi-based electrocatalysts have demonstrated promising catalytic activity for CO₂ reduction to HCOOH by stabilizing the *OCHO intermediate. Interface engineering of two different materials has been an emerging strategy to promote catalytic performance. For instance, charge transfer at the interface between two different Bi-based materials led to optimizing the binding energy of adsorbates and lowered the thermodynamic energy barrier. However, the effect of semiconductor/cocatalyst interface on catalytic performance has been rarely investigated even though there have been a number of reports of PEC CO₂ reduction to HCOOH by integrating photocathodes and cocatalysts. Thermodynamically feasible production of HCOOH by Bi₂O₃—GaN binary systems compared to each material of Bi₂O₃ and GaN revealed that the design rule of heterogeneous catalysis can be applied to PEC reactions.

Compared to the previous photocathodes, the Bi/GaN/Si photocathodes described herein exhibited excellent PEC CO₂ RR activity with a low onset-potential (0.2 V_{RHE}), high FE_{HCOOH} (98% at −0.3 V_{RHE}), j_{HCOOH} (10.3 mA/cm² at −0.6 V_{RHE}), and prolonged stability (12 h) due to beneficial Bi—GaN interaction. What is more, the PEC CO₂ reduction reaction operated at a much lower applied bias than electrocatalysis using Bi-based electrocatalysts because the built-in-potential formed in photocathode (n⁺-p Si) positively shifted the reduction potentials. While the design of the disclosed photocathodes is more challenging than the fabrication of an electrocatalyst (e.g., due to considering not only the catalytic activity but also the light absorption and the interfacial electronic interaction between semiconductor and cocatalyst), the disclosed Bi/GaN/Si photocathode nonetheless exhibited excellent performance in terms of catalytic activity, optical transmittance, and electronic band alignment, establishing a highly promising architecture for efficient and stable solar-fuel production.

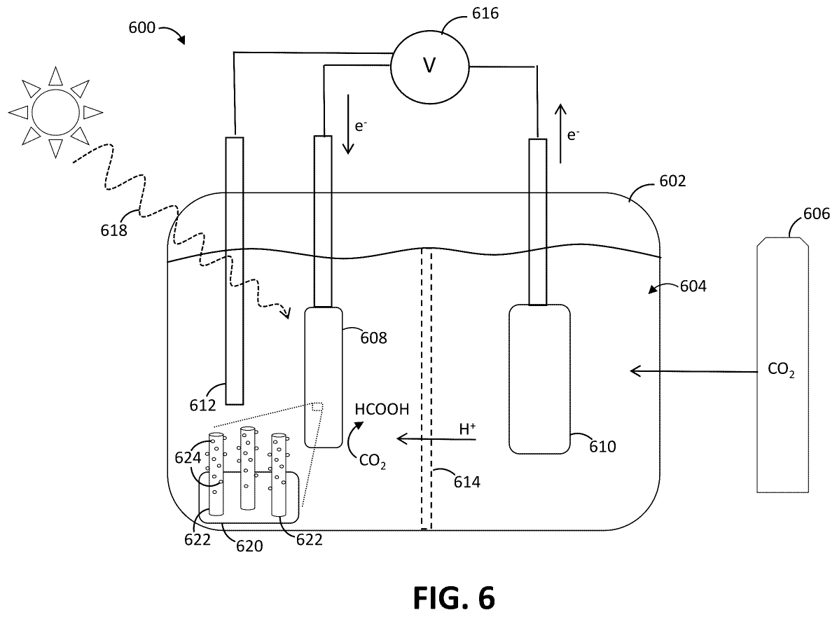

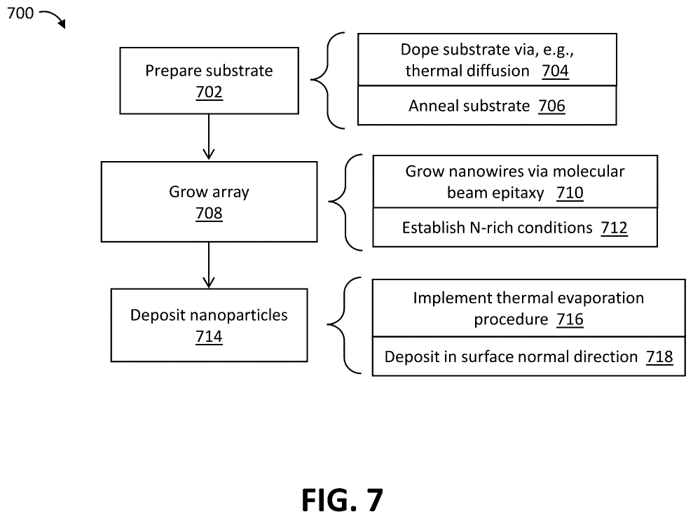

The analyses presented above demonstrated that photocathodes having Bi nanoparticles and GaN nanowires are useful for conversion of CO₂ to HCOOH. A number of examples of the photocathodes are now described in connection with the schematic diagram of FIG. 6 and the flow diagram of FIG. 7.

FIG. 6 depicts a system 600 for reduction of CO₂ into formic acid in accordance with one example. The system 600 may also be configured for alternative or additional reactions, including, for instance, the evolution of H₂, the N₂ reduction reaction, and the NO₃ reduction reaction. The system 600 may be configured as an electrochemical system. In this example, the electrochemical system 600 is a photoelectrochemical (PEC) system in which solar or other radiation is used to facilitate the CO₂ reduction. The manner in which the PEC system 600 is illuminated may vary. In thermochemical examples, the source of radiation may be replaced by a heat source.

The electrochemical system 600 includes one or more electrochemical cells 602. A single electrochemical cell 602 is shown for ease in illustration and description. The electrochemical cell 602 and other components of the electrochemical system 600 are depicted schematically in FIG. 6 also for ease in illustration. The cell 602 contains an electrolyte solution 604 to which a source 606 of CO₂ is applied. Potassium bicarbonate KHCO₃ may be used as an electrolyte. Additional or alternative electrolytes may be used. Further details regarding an example of the electrochemical system 600 are provided hereinabove.

The electrochemical cell 602 includes a working electrode 608, a counter electrode 610, and a reference electrode 612, each of which is immersed in the electrolyte 604. The counter electrode 610 may be or include a metal wire or mesh, such as a platinum wire or mesh. The reference electrode 612 may be configured as a reversible hydrogen electrode (RHE). The configuration of the counter and reference electrodes 610, 612 may vary. For example, the counter electrode 610 may be configured as, or otherwise include, a photoanode at which water oxidation (2H₂O⇔O2+4e⁻+4H⁺) occurs.

Both reduction of CO₂ and evolution of H₂ may occur at the working electrode 612 as follows:

CO₂ reduction: CO₂+2H⁺+2e⁻ [symbol] CHOOH

H₂ evolution: 2H⁺+2e⁻ [symbol] H₂

To that end, electrons flow from the counter electrode 610 through a circuit path external to the electrochemical cell 602 to reach the working electrode 608. The working and counter electrodes 608, 610 may thus be considered a cathode and an anode, respectively. The competition between reduction of CO₂ and evolution of H₂ may be managed or controlled (e.g., to favor CO₂ reduction) via the composition of the components of the nanoarchitecture and/or the applied voltage, as described herein.

In the example of FIG. 6, the working and counter electrodes are separated from one another by a membrane 614, e.g., a proton-exchange membrane. In some cases, the membrane 614 is configured as, or otherwise includes, a Nafion membrane. The construction, composition, configuration and other characteristics of the membrane 614 may vary.

In this example, the circuit path includes a voltage source 616 of the electrochemical system 600. The voltage source 616 is configured to apply a bias voltage between the working and counter electrodes 608, 610. The bias voltage may be used to establish a ratio of CO₂ reduction to hydrogen (H₂) evolution at the working electrode, as described further below. The circuit path may include additional or alternative components. For example, the circuit path may include a potentiometer in some cases.

In some cases, the working electrode 608 is configured as a photocathode. Light 618, such as solar radiation, may be incident upon the working electrode 608 as shown. The electrochemical cell 602 may thus be considered and configured as a photoelectrochemical cell. In such cases, illumination of the working electrode 608 may cause charge carriers to be generated in the working electrode 608. Electrons that reach the surface of the working electrode 608 may then be used in the CO₂ reduction and/or the H₂ evolution. The photogenerated electrons augment the electrons provided via the current path. The photogenerated holes may move to the counter electrode for the water oxidation. A number of examples of, and further details regarding, photocathodes are provided hereinabove in connection with, for instance, FIGS. 1-5.

The working electrode 608 includes a substrate 620. The substrate 620 of the working electrode 608 may constitute a part of an architecture, or a support structure, of the working electrode 608. The substrate 620 may be uniform or composite. For example, the substrate 620 may include any number of layers or other components. The substrate 620 thus may or may not be monolithic. The shape of the substrate 620 may also vary. For instance, the substrate 620 may or may not be planar or flat.

The substrate 620 of the working electrode 608 may be active (functional) and/or passive (e.g., structural). In the latter case, the substrate 620 may be configured and act solely as a support structure for a catalyst arrangement formed along an exterior surface of the working electrode 608, as described below. Alternatively or additionally, the substrate 620 may be composed of, or otherwise include, a material suitable for the growth or other deposition of the catalyst arrangement of the working electrode 608.

The substrate 620 may include a light absorbing material. The light absorbing material is configured to generate charge carriers upon solar or other illumination. The light absorbing material has a bandgap such that incident light generates charge carriers (electron-hole pairs) within the substrate. Some or all of the substrate 620 may be configured for photogeneration of electron-hole pairs. To that end, the substrate 620 may be composed of, or otherwise include, a semiconductor material. In some cases, the substrate 620 is composed of, or otherwise includes, silicon. For instance, the substrate 620 may be provided as a silicon wafer. The silicon may be doped. In some cases, the substrate 620 is heavily n-type doped, and moderately or lightly p-type doped, to form a junction. The doping arrangement may vary. For example, one or more components of the substrate 620 may be non-doped (intrinsic), or effectively non-doped. The substrate 620 may include alternative or additional layers, including, for instance, support or other structural layers. In other cases, the substrate 620 is not light absorbing. In these and other cases, one or more other components of the photocathode (e.g., nanowires) may be composed of, or otherwise include, a semiconductor material configured to act as a light absorber. Thus, in photoelectrochemical cases, the semiconductor material of the substrate and/or other components supported by the substrate may be configured to generate charge carriers upon absorption of solar (or other) radiation, such that the chemical cell is configured as a photoelectrochemical system.

The substrate 620 of the working electrode 608 establishes a surface at which a catalyst arrangement of the electrode 608 is provided. The catalyst arrangement includes a conductive projection (e.g., nanowire)-nanoparticle architecture as described herein.

The electrode 608 includes an array of nanowires 622 and/or other conductive projections supported by the substrate 620. Each nanowire 622 extends outward from the surface of the substrate 620. The nanowires 622 may thus be oriented in parallel with one another. Each nanowire 622 has a semiconductor composition for catalytic conversion of carbon dioxide (CO₂) in the chemical cell 602 into, e.g., formic acid. In some cases, the semiconductor composition includes gallium nitride (GaN). Additional or alternative semiconductor materials may be used, including, for instance, indium nitride, indium gallium nitride, aluminum nitride, boron nitride, aluminum oxide, silicon, and/or their alloys.

The nanowires 622 may facilitate the conversion in one or more ways. For instance, each nanowire 622 may be configured to extract the charge carriers (e.g., electrons) generated in the substrate 620. The extraction brings the electrons to external sites along the nanowires 622 for use in the CO₂ reduction. The composition of the nanowires 622 may also form an interface well-suited for reduction of CO₂, as explained below.

Each nanowire 622 may be or include a columnar, post-shaped, or other elongated structure that extends outward (e.g., upward) from the plane of the substrate 620. The nanowires 622 may be grown or formed as described in U.S. Pat. No. 8,563,395, the entire disclosure of which is hereby incorporated by reference. The dimensions, size, shape, composition, and other characteristics of the nanowires 622 (and/or other conductive projections) may vary. For instance, each nanowire 622 may or may not be elongated like a nanowire. Thus, other types and shapes of nanostructures or other conductive projections from the substrate 620, such as various shaped nanocrystals, may be used.

In some cases, one or more of the nanowires 622 is configured to generate electron-hole pairs upon illumination. For instance, the nanowires 622 may be configured to absorb light at frequencies different than other light absorbing components of the electrode 608. For example, one light absorbing component, such as the substrate 620, may be configured for absorption in the visible or infrared wavelength ranges, while another component may be configured to absorb light at ultraviolet wavelengths. In other cases, the nanowires 622 are the only light absorbing component of the electrode 608.

The electrode 608 further includes nanoparticles 624 disposed over the array of nanowires 622. Each nanoparticle 624 is configured for the catalytic conversion of carbon dioxide (CO₂) in the chemical cell 602. A plurality of the nanoparticles 624 are disposed on each nanowire 622, as schematically shown in FIG. 6. The nanoparticles 624 are distributed across the outer surface of each nanowire 622. For example, each nanowire 622 has a plurality of the nanoparticles 624 distributed across or along sidewalls of the nanowire 622. The nanoparticles 624 may also be disposed on a top or upper surface of each nanowire 622. The distribution of the nanoparticles 624 may vary. As described herein, each nanoparticle 624 may include or be composed of a Group V metal or metalloid for the reduction of carbon dioxide (CO₂) in the chemical cell 602.

The Group VA metal or metalloid may be or include Bi. Alternative or additional compositions may be used, including alloys of Bi. The use of alternative or additional metals may lead to alternative or additional reduction products of the CO₂ conversion. In some cases, additional nanoparticles may be used, including nanoparticles composed of, or otherwise including one or more noble metals, such as gold.

As described above, some or all of the nanoparticles may have a core-shell arrangement in which a core includes the Group VA element and a shell includes an amorphous oxide material. The nanoparticles may have a size falling in a range from about 3 nm to about 20 nm. The shell may have a thickness falling in a range from about 2 nm to about 5 nm.

The nanoparticles 624 may be sized in a manner to facilitate the CO₂ reduction. The size of the nanoparticles 624 may be useful in catalyzing the reaction, as described herein. The size of the nanoparticles 624 may promote the CO₂ reduction in additional or alternative ways. For instance, the nanoparticles 624 may also be sized to avoid inhibiting the illumination of the light absorber (e.g. the substrate 620).

The manner in, or extent to, which the array of nanowires 622 is ordered may vary. In some cases, the nanowires 622 may be arranged laterally in a regular or semi-regular pattern. In other cases, the lateral arrangement of the nanowires 622 is irregular. In such cases, the ordered nature of the nanowires 622 is instead limited to the parallel orientation of the nanowires 622.

In some cases, each nanowire 622 is coated with the nanoparticles 624. The extent of the coating may vary. For instance, a top surface of each nanowire 622 may be entirely coated with the nanoparticles 624, while one or more portions of the sidewalls of the nanowires 622 may be partially coated. The distribution of the nanoparticles 624 may accordingly be uniform or non-uniform. The nanoparticles 624 may thus be distributed randomly across each nanowire 622. The schematic arrangement of FIG. 6 is shown for ease in illustration.

The nanowires 622 and the nanoparticles 624 are not shown to scale in the schematic depiction of FIG. 6. The shape of the nanowires 622 and the nanoparticles 624 may also vary from the example shown.

FIG. 7 depicts a method 700 of fabricating an electrode of an electrochemical system in accordance with one example. The method 700 may be used to manufacture any of the working electrodes described herein or another electrode or device. The method 700 may include additional, fewer, or alternative acts. For instance, the method 700 may or may not include one or more acts directed to fabricating a substrate (act 404).

The method 400 may begin with an act 402 in which a substrate is prepared. The substrate may be or be formed from a p-n Si wafer. In one example, a 2-inch Si wafer was used, but other (e.g., larger) size wafers may be used. Other semiconductors and substrates may be used. Preparation of the substrate may include one or more cleaning procedures.

The act 702 may include an act 704 in which the substrate is doped. Thermal diffusion and/or other procedures may be used. The doping may be directed to forming a junction. The substrate may accordingly be doped with p-type dopant(s) and n-type dopant(s). An act 706 may then be implemented to anneal the substrate.

In some cases, an n⁺-p silicon junction of the substrate is formed through a standard thermal diffusion process using, e.g., a (100) silicon wafer. For instance, phosphorus and boron as n-type and p-type dopants, respectively, may be deposited on the front and back sides of the polished p-Si (100) wafer by spin-coating, but other dopants may be used. The wafer may then be annealed, e.g., at 950 degrees Celsius under nitrogen atmosphere for four hours. The process parameters may vary in other cases. For instance, the wafer may be annealed at 900 or 950 degrees Celsius under argon atmosphere.

In the example of FIG. 7, the method 700 includes an act 708 in which GaN or other nanowire arrays (or other conductive projections) are grown or otherwise formed on the substrate. Each nanowire (or other conductive projection) has a semiconductor composition as described herein. The nanowire growth may be achieved in an act 710 in which plasma-assisted molecular beam epitaxy (MBE) is implemented. The growth may be implemented under nitrogen-rich conditions in accordance with an act 712.

In one example, plasma-assisted MBE was used for growing GaN nanowires on silicon wafer under nitrogen-rich conditions to promote the formation of a N-terminated surface to protect against photocorrosion and oxidation. The substrate temperature was 790° C. and the growth duration was about 2 hours. The forward plasma power was 350 W with a Ga flux beam equivalent pressure (BEP) of 5×10⁻⁸ Torr.

The growth parameters may vary in other cases. For instance, in another example, the growth conditions were as follows: a growth temperature of 790° C. for 1.5 hours, a Ga beam equivalent pressure of about 6×10⁻⁸ Torr, a nitrogen flow rate of 1 standard cubic centimeter per minute (sccm), and a plasma power of 350 Watts. The substrate and the nanowires provide or act as scaffolding for the catalysts deposited in the following steps.

In an act 714, Bi and/or other nanoparticles are deposited across each nanowire or other conductive projection. In one example, nanoparticles were deposited on GaN nanowires by a thermal evaporation procedure in an act 716. The nanoparticles may be deposited in a surface normal direction in accordance with an act 718. In one example, a deposition rate of 0.1 nm/s was used under a base pressure of 1×10⁻⁶ Torr, but the process parameters may vary. Other types of deposition procedures may be used, including, for instance, electron beam deposition.

At this stage of the method 700, each nanoparticle may have a metallic composition. For instance, the nanoparticles may be composed of, or otherwise include, Bi. Subsequent handling or use of the photoelectrode may result in the formation of an oxide shell as described herein. The method 700 may accordingly include one or more acts directed to formation of a core-shell configuration of the nanoparticles.

Examples of photocathodes and other devices including Bi decorated conductive projections (e.g., GaN nanowires) integrated on a substrate, e.g., planar silicon (Si), for the conversion of CO₂ gas to HCOOH have been described. The disclosed photocathodes demonstrated the unique electronic interaction at the interface between the Bi nanoparticles and the GaN nanowires, which resulted in a significant boost of catalytic activity for CO₂ reaction on a silicon photocathode. The Bi nanoparticle catalysts supported on the GaN/Si architecture are highly active and selective for PEC CO₂ reduction toward HCOOH. This unique design allows efficient solar light absorption and charge carrier transport, and further exposes the abundant catalytic active sites. The DFT calculations provided above indicate that the binary co-catalyst arrangement of Bi and GaN favors CO₂ conversion to HCOOH, working in synergy to enhance electron transfer from the GaN nanowires to the Bi nanoparticles and reduce the reaction energy barrier by stabilizing key reaction intermediates of OCHO*.

The term “about” is used herein to include deviations from a specified value that are effectively the same as the specified value, including, for instance, deviations that do not result in a detectable or discernable change in outcome.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device for catalytic conversion of carbon dioxide (CO₂), the device comprising:
a substrate having a surface;
an array of conductive projections supported by the substrate and extending outward from the surface of the substrate, each conductive projection of the array of conductive projections having a semiconductor composition; and
a plurality of nanoparticles disposed over the array of conductive projections, each nanoparticle of the plurality of nanoparticles being configured for the catalytic conversion of carbon dioxide (CO₂);
wherein each nanoparticle of the plurality of nanoparticles comprises a Group VA element, the Group VA element being a metal or a metalloid.

2. The device of claim 1, wherein the Group VA element is bismuth.

3. The device of claim 1, wherein the Group VA element is selected from the group consisting of antimony and bismuth.

4. The device of claim 1, wherein respective nanoparticles of the plurality of nanoparticles have a core-shell arrangement in which a core comprises the Group VA element and a shell comprises an amorphous oxide material.

5. The device of claim 4, wherein the shell has a thickness falling in a range from about 2 nm to about 5 nm.

6. The device of claim 1, wherein:
the substrate comprises a semiconductor material; and
the semiconductor material is doped to define a junction to generate charge carriers upon absorption of solar radiation.

7. The device of claim 6, wherein each conductive projection of the array of conductive projections comprises a nanowire configured to extract the charge carriers generated in the substrate.

8. The device of claim 1, wherein the substrate comprises silicon.

9. The device of claim 1, wherein the semiconductor composition comprises gallium nitride.

10. The device of claim 1, wherein respective nanoparticles of the plurality of nanoparticles have a size falling in a range from about 3 nm to about 20 nm.

11. An electrochemical system comprising a working electrode configured in accordance with the device of claim 1, and further comprising:
a counter electrode;
an electrolyte in which the working and counter electrodes are immersed; and
a voltage source that applies a bias voltage between the working and counter electrodes;
wherein the bias voltage is set to a level for conversion of CO₂ into formic acid at the working electrode.

12. A photocathode for a photoelectrochemical cell, the photocathode comprising:
a substrate comprising a semiconductor material, the semiconductor material being doped to generate charge carriers upon solar illumination;
an array of nanostructures supported by the substrate, each nanostructure of the array of nanostructures being configured to extract the charge carriers from the substrate, each nanostructure of the array of nanostructures comprising gallium nitride; and
a plurality of nanoparticles distributed across each nanostructure of the array of nanostructures, each nanoparticle of the plurality of nanoparticles being configured for the catalytic conversion of carbon dioxide (CO₂) in the photoelectrochemical cell into formic acid;
wherein each nanoparticle of the plurality of nanoparticles comprises a Group VA element, the Group VA element being a metal or a metalloid.

13. The photocathode of claim 12, wherein the Group VA element is bismuth.

14. The photocathode of claim 12, wherein respective nanoparticles of the plurality of nanoparticles have a core-shell arrangement in which a core comprises the Group VA element and a shell comprises an amorphous oxide material.

15. A photoelectrochemical system comprising a working photocathode configured in accordance with the photocathode of claim 12, and further comprising:
a counter electrode;
an electrolyte in which the working photocathode and the counter electrode are immersed; and
a voltage source that applies a bias voltage between the working photocathode and the counter electrode;
wherein the bias voltage is set to a level for conversion of CO₂ into formic acid at the working photocathode.

16. A method of fabricating a device for catalytic conversion of carbon dioxide (CO₂), the method comprising:
growing an array of conductive projections on a semiconductor substrate, each conductive projection of the array of conductive projections having a semiconductor composition; and
depositing a plurality of nanoparticles across each conductive projection of the array of conductive projections, each nanoparticle of the plurality of nanoparticles being configured for the catalytic conversion of carbon dioxide (CO₂),
wherein each nanoparticle of the plurality of nanoparticles comprises a Group VA element, the Group VA element being a metal or a metalloid.

17. The method of claim 16, wherein the Group VA element is bismuth.

18. The method of claim 16, wherein forming the array of conductive projections comprises growing an array of nanowires on the semiconductor substrate, each nanowire of the array of nanowires having a semiconductor composition for the catalytic conversion of carbon dioxide (CO₂).

19. The method of claim 18, wherein growing the array of nanowires comprises implementing a molecular beam epitaxy (MBE) procedure under nitrogen-rich conditions.

20. The method of claim 16, wherein depositing the plurality of nanoparticles comprises implementing a thermal evaporation procedure to deposit bismuth nanoparticles on the array of conductive projections.
